(19) United States
(12) Patent Application Publication
(10) Pub. No.: US 2023/0134208 A1
(43) Pub. Date: May 4, 2023

(54) WORD LINE STRUCTURE AND METHOD FOR FORMING SAME AND SEMICONDUCTOR STRUCTURE

(71) Applicant: CHANGXIN MEMORY TECHNOLOGIES, INC., Hefei (CN)

(72) Inventors: SEMYEONG JANG, Hefei (CN); JOONSUK MOON, Hefei (CN); Deyuan XIAO, Hefei (CN); JO-LAN CHIN, Hefei (CN)

(21) Appl. No.: 17/892,148

(22) Filed: Aug. 22, 2022

(30) Foreign Application Priority Data
Oct. 29, 2021 (CN) 202111273068.3

(51) Int. Cl. H01L 27/108; H01L 29/423; H01L 29/40; H01L 29/49; H01L 23/522; H01L 23/528; H01L 23/532

(52) U.S. Cl. CPC H01L 27/10891; H01L 29/42392; H01L 29/401; H01L 29/4908; H01L 23/5222; H01L 23/5283; H01L 23/53266; H01L 23/53295; H01L 23/53271; H01L 27/10885

(57) ABSTRACT

Embodiments provides a word line structure and a method for forming the same, and a semiconductor structure, relating to the field of memory technologies. The method for forming a word line structure includes: providing a base substrate including a substrate, and forming a plurality of word line trenches and a plurality of active area pillars arranged at intervals in the substrate; forming insulating layers on the plurality of active area pillars, and filling a first spacer between adjacent two of the insulating layers; processing each of the insulating layers, and forming an annular gate on the processed insulating layer; etching back the first spacer, such that a top of the first spacer is lower than a bottom of the annular gate; and depositing a second spacer at a top of the annular gate, and forming an air gap structure between the first spacer and the second spacer.

### CROSS-REFERENCE TO RELATED APPLICATION

The present disclosure claims priority to Chinese Patent Application No. 202111273068.3, titled “WORD LINE STRUCTURE AND METHOD FOR FORMING SAME AND SEMICONDUCTOR STRUCTURE” and filed to the State Patent Intellectual Property Office on Oct. 29, 2021, the entire contents of which are incorporated herein by reference.

### TECHNICAL FIELD

The present disclosure relates to the field of memory technologies, and more particularly, to a word line structure and a method for forming a word line structure, and a semiconductor structure.

### BACKGROUND

As a memory component configured to store programs and various data and information, a memory is generally used as an internal semiconductor integrated circuit in computers or other electronic devices. There are various types of memories such as random access memory (RAM), read-only memory (ROM), dynamic random access memory (DRAM), static random access memory (SRAM), and flash memory. The DRAM is widely used in mobile devices such as mobile phones and tablet computers because it has a smaller size, a higher integration, and a faster data transfer speed, etc.

In a basic memory cell device of the DRAM, in existing vertical gate-all-around (VGAA) technologies, a word line structure generally includes an oxide insulating layer and a metal gate formed by titanium nitride. After the word line structure is formed, metal annular gates are isolated by a silicon nitride layer. Because an arrangement density of semiconductors on a substrate is larger, a distance between the metal annular gates on the adjacent semiconductors is closer. As a result, during use of the device, parasitic capacitances between the metal annular gates of the word line structure is larger, delay noise is higher, and performance of the device is poorer.

It is to be noted that the information disclosed in the above background art section is only for enhancement of understanding of the background of the present disclosure, and therefore may include information that does not constitute the prior art that is already known to a person of ordinary skill in the art.

### SUMMARY

An objective of the present disclosure is to provide a word line structure and a method for forming a word line structure and a semiconductor structure to overcome the deficiencies in the prior art.

Other features and advantages of the present disclosure will become apparent from the following detailed description, or in part, by practice of the present disclosure.

According to a first aspect of the present disclosure, there is provided a method for forming a word line structure, including:

providing a base substrate comprising a substrate, and forming a plurality of word line trenches and a plurality of active area pillars arranged at intervals in the substrate;

forming insulating layers on the plurality of active area pillars, and filling a first spacer between adjacent two of the insulating layers;

processing each of the insulating layers, and forming an annular gate on the processed insulating layer;

etching back the first spacer, such that a top of the first spacer is lower than a bottom of the annular gate; and

depositing a second spacer at a top of the annular gate, and forming an air gap structure between the first spacer and the second spacer.

According to a second aspect of the present disclosure, there is provided a word line structure, which includes:

a plurality of word line trenches; and

a plurality of active area pillars, the plurality of active area pillars being divided by the plurality of word line trenches, wherein an insulating layer is arranged on each of the plurality of active area pillars, an annular gate is arranged on the insulating layer, a spacer is arranged between adjacent two of the annular gates, and an air gap structure is arranged in the spacer.

According to a third aspect of the present disclosure, there is provided a semiconductor structure, which includes:

a plurality of bit line structures and the plurality of word line structure as described above.

The plurality of bit line structures and the plurality of word line structures are arranged vertically.

The present disclosure provides a method for forming a word line structure. In one aspect, a plurality of insulating layers are formed on a plurality of active area pillars, a plurality of annular gates are formed on the plurality of insulating layers, and a first spacer and a second spacer are formed in front of adjacent two of the plurality of active area pillars, and an air gap structure is formed between the first spacer and the second spacer. The formation of the air gap structure can reduce a parasitic capacitance between adjacent two of the plurality of annular gates. Because of the reduced parasitic capacitance, delay noise can be reduced, and device performance can be improved.

In another aspect, the plurality of active area pillars in the word line structure are over etched, such that a distance between adjacent two of the plurality of active area pillars is increased, and the allowance for the semiconductor integration process is improved.

Finally, in the word line structure provided in the present disclosure, a double-layer insulating dielectric layer is formed at a top of a given one of the plurality of active area pillars, such that the insulating performance of the word line structure is improved, thereby preventing the occurrence of a short circuit between the word line structure and a surrounding structure.

It is to be understood that the above general description and the detailed description below are merely exemplary and explanatory, and do not limit the present disclosure.

### BRIEF DESCRIPTION OF THE DRAWINGS

The accompanying drawings here are incorporated in and constitute a part of this specification, illustrate embodiments conforming to the present disclosure and, together with the specification, serve to explain the principles of the present disclosure. Apparently, the accompanying drawings in the following description show merely some embodiments of the present disclosure, and persons of ordinary skill in the art may still derive other drawings from these accompanying drawings without creative efforts.

FIG. 1 is a flowchart of a method for forming a word line structure according to an exemplary embodiment of the present disclosure;

FIG. 2 is a flowchart of processing an insulating layer in a method for forming a word line structure according to an exemplary embodiment of the present disclosure;

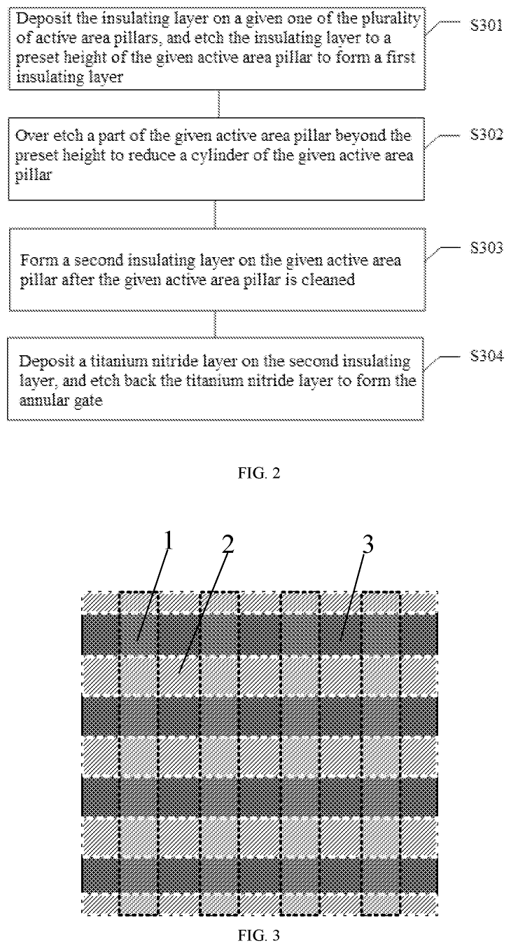

FIG. 3 is a top view of an existing semiconductor structure according to an exemplary embodiment of the present disclosure;

FIG. 4 is a diagram from a perspective of a word line in the semiconductor structure in FIG. 3 according to an exemplary embodiment of the present disclosure;

FIG. 5 is a diagram from the perspective of a bit line in the semiconductor structure in FIG. 3 according to an exemplary embodiment of the present disclosure;

FIGS. 6 to 13 are schematic structural diagrams of a method for forming a word line structure according to an exemplary embodiment of the present disclosure;

FIG. 14 is a schematic structural diagram from the perspective of a word line in a word line structure according to an exemplary embodiment of the present disclosure; and

FIG. 15 is a schematic structural diagram from the perspective of a bit line in a word line structure according to an exemplary embodiment of the present disclosure.

Reference numerals are described as follows:

1: word line trench; 11: silicon nitride; 12: titanium nitride; 2: active area pillar;

3: bit line trench; 4: base substrate; 5: insulating layer; 51: first insulating layer;

52: second insulating layer; 6: spacer: 61: first spacer; 62: second spacer; and

7: titanium nitride layer; 8: air gap structure; and 9: cobalt silicide diffusion ring.

### DETAILED DESCRIPTION

Exemplary embodiments will now be described more comprehensively with reference to the accompanying drawings. However, the exemplary embodiments may be carried out in various manners, and shall not be interpreted as being limited to the embodiments set forth herein; instead, providing these embodiments will make the present disclosure more comprehensive and complete, and will fully convey the conception of the exemplary embodiments to those skilled in the art. Throughout the drawings, similar reference signs indicate the same or similar structures, and thus their detailed description will be omitted. In addition, the accompanying drawings are merely exemplary illustration of the present disclosure, and are not necessarily drawn to scale.

Furthermore, in the following detailed description, for convenience of explanation, numerous details are set forth to provide a thorough understanding of the embodiments of the present disclosure. Obviously, however, one or more embodiments may also be practiced without these details.

“On”, “formed on” and “arranged on” as used herein may mean that one layer is directly formed or arranged on another one, or may mean that one layer is indirectly formed or arranged on another one, that is, there are other layer between the two layers.

The terms “one”, “a”, “the”, “said”, and “at least one” are intended to mean that there exists one or more elements/constituent parts/etc. The terms “comprising” and “having” are intended to be inclusive and mean that there may be additional elements/constituent parts/etc. other than the listed elements/constituent parts/etc.

It should be noted that, although the terms “first”, “second”, etc. may be used herein to describe various components, members, elements, regions, layers and/or parts, these components, members, elements, regions, layers and/or parts shall not be limited by these terms. Rather, these terms are used to distinguish one component, member, element, region, layer and/or part from another.

In the present disclosure, unless otherwise described, the used term “arranged in the same layer” refers to a case where two layers, components, members, elements or parts may be formed by the same composition process and, furthermore, the two layers, components, members, elements or parts are generally formed by the same material.

In the related art, Vertical Gate All Around (VGAA) is a common form of gate in a basic memory cell of a DRAM. To ensure the high performance of the memory, as many active areas and VGAA gates as possible are generally arranged on a base substrate of the memory. Therefore, a density of the VGAA gates is increased in limited space of the base substrate, interference between two adjacent gates is increased, and a parasitic capacitance becomes larger. As a result, performance of the memory is adversely affected.

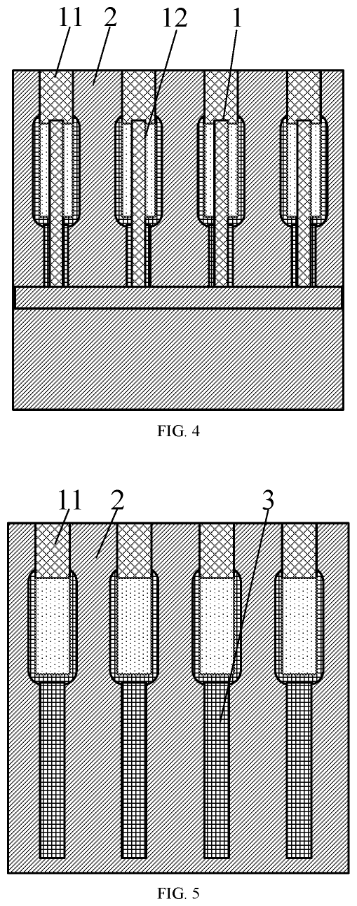

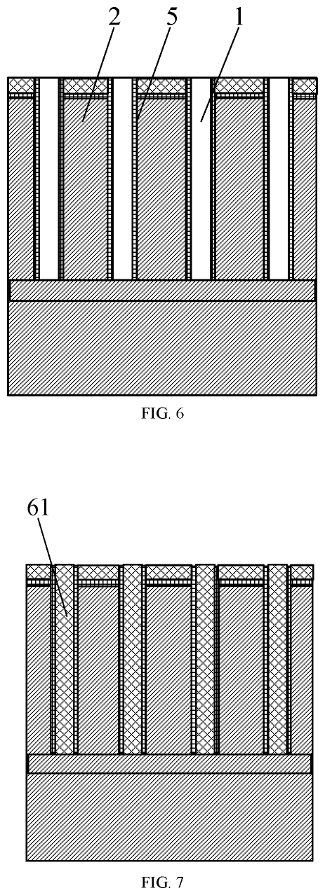

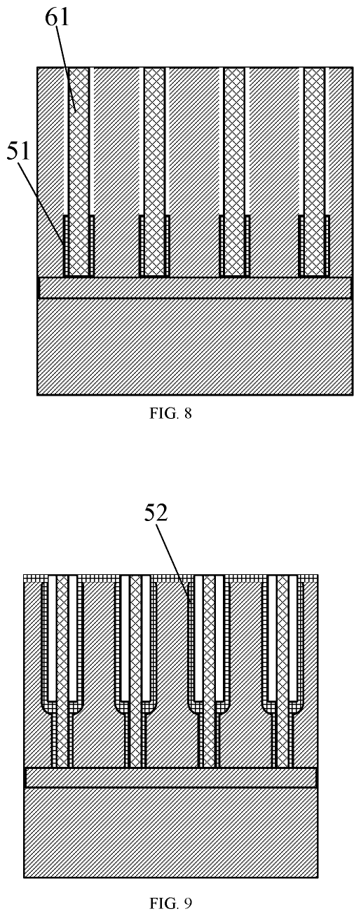

At present, in the VGAA technology, as shown in FIG. 3 to FIG. 5, FIG. 3 is a top view of an existing semiconductor structure, FIG. 4 is a diagram of the semiconductor structure from the perspective of a word line, and FIG. 5 is a diagram of the semiconductor structure from the perspective of a bit line. As can be seen from the figures, a word line trench 1 and a bit line trench 3 are arranged vertically. In a mainstream word line structure, the word line trench1 divide a substrate into a plurality of active area pillars 2. Insulating layers are formed on the active area pillars 2. Next, titanium nitride forms titanium nitride 12 on the insulating layers. The titanium nitride 12 is processed by a process to form annular gates, and adjacent two of the annular gates are isolated by silicon nitride 11. Therefore, a dielectric layer is provided between the adjacent two annular gates, such that a larger parasitic capacitance is generated between the adjacent two annular gates, leading to larger delay noise, and thus having a negative effect on performance of the memory. Therefore, the present disclosure provides a method for forming a word line structure, which can improve the deficiencies of the above-mentioned memory.

A 4F2 VGAA semiconductor structure is introduced in the embodiments of the present disclosure, where 4F2 refers to an arrangement form with 2×2 minimum integral units on the semiconductor structure, and a gate form of the semiconductor is an annular gate perpendicular to a base substrate. However, the arrangement of the minimum integral units of the semiconductor in the present disclosure is not limited thereto.

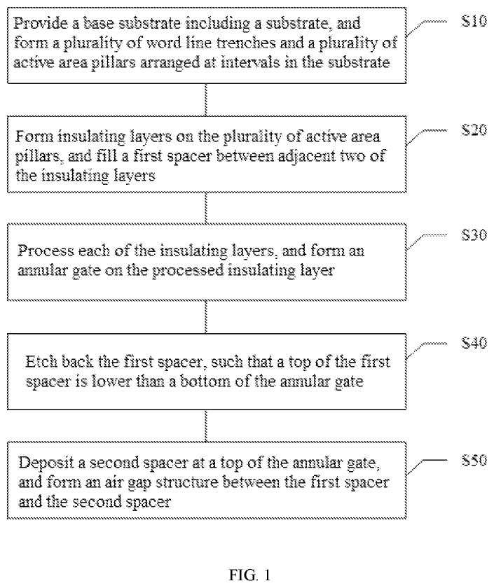

Embodiments of the present disclosure provide a method for forming a word line structure. As shown in FIG. 1, the method for forming a word line structure includes:

Step S10: providing a base substrate comprising a substrate, and forming a plurality of word line trenches and a plurality of active area pillars arranged at intervals in the substrate;

Step S20: forming insulating layers on the plurality of active area pillars, and filling a first spacer between adjacent two of the insulating layers;

Step S30: processing each of the insulating layers, and forming an annular gate on the processed insulating layer;

Step S40: etching back the first spacer, such that a top of the first spacer is lower than a bottom of the annular gate; and

Step S50: depositing a second spacer at a top of the annular gate, and forming an air gap structure between the first spacer and the second spacer.

The above steps are described in detail below.

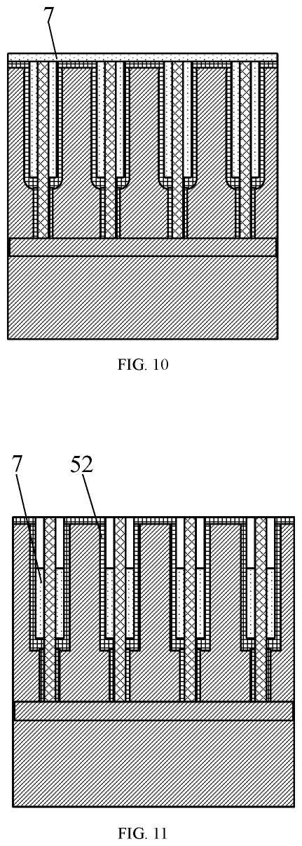

In Step S10, as shown in FIG. 6, a base substrate 4 may be provided, where the base substrate 4 includes a substrate, and a plurality of word line trenches 1 are arranged in the substrate at intervals and a plurality of active area pillars 2 are distributed in the substrate side by side.

The base substrate may be a flat plate-shaped structure. A shape of the base substrate may be a rectangle or a square, but is not limited thereto. The shape of the base substrate also may be a circle, an ellipse, a polygon or the like. In addition, a material of the base substrate may be silicon, but is not limited thereto. The material of the base substrate may be other semiconductor material. Neither the shape nor the material of the base substrate are particularly limited in the present disclosure, and selection of the shape and the material of the base substrate may be determined according to actual usage requirements.

A manner of forming the plurality of word line trenches 1 on the base substrate may include: etching the base substrate by means of a mask, to form the plurality of word line trenches 1 arranged at intervals. However, the manner of forming the word line trenches in the present disclosure is not limited thereto. Other manners may also be employed to form the word line trenches, which may be determined according to actual usage requirements.

A depth of the word line trench 1 is not limited in the present disclosure. The word line trenches may be shallow trench structures or may be other trench structures with different depths. The depth of the word line trench may be set according to actual requirements, which is not limited in the present disclosure.

In this step, the plurality of word line trenches 1 and the plurality of active area pillars 2 are distributed at intervals. The active area pillars are semiconductor material pillar bodies in an active area that are isolated by the plurality of word line trenches on the base substrate. The shape of the active area pillar 2 may be a cuboid pillar body or may be other cuboid shape. The concrete shape of the active area pillar is determined according to a distribution form of the word line trenches on the base substrate, and is not limited in the present disclosure.

In Step S20, as shown in FIG. 6 and FIG. 7, insulating layers 5 are formed on the plurality of active area pillars 2, and a first spacer 61 is filled between adjacent two of the insulating layers 5.

After the plurality of word line trenches 1 and the plurality of active area pillars 2 are formed on the base substrate 4, a photoresist is formed on a surface of the word line structure to deposit an oxide on the base substrate by using a mask. The oxide is deposited at a periphery and a top of the active area pillar to form the insulating layer 5. After the first spacer is formed, the photoresist is stripped, a silicon nitride layer is filled between adjacent two of the insulating layers, and silicon nitride is filled at the top of the insulating layer to form the first spacer 61.

A material of the insulating layer 5 is an oxide such as silicon oxide. The insulating layer 5 may be an oxide film where silicon oxide is doped with B₂O₃ or P₂O₅ and so on, or may also be a low-k dielectric insulating film layer where silicon dioxide is doped with F and CH₃. Concrete compositions of the insulating layers are not limited in the present disclosure, provided that functions and effects of the insulating layers in the present disclosure are satisfied.

In Step S30, as shown in FIG. 8 to FIG. 11, each of the insulating layers is processed, and an annular gate is formed on the processed insulating layer.

After the insulating layers 5 are formed, the first spacer at the top of the word line structure needs to be removed first to facilitate subsequent processing of the insulating layers and the first spacer. The first spacer at the top of the word line structure may be removed by means of chemical mechanical polishing (CMP). After the first spacer at the top of the word line structure is removed, the top of the active area pillar and the top of the word line trench can be exposed to facilitate subsequent processing steps.

The CMP is a processing technique that combines chemical corrosion and mechanical removal. In pure chemical polishing, surface precision is higher, damage is lower, and a surface or a subsurface is not prone to damage, but its polishing rate is lower, and its polishing consistency is poorer. In pure mechanical polishing, the consistency is better, and the polishing rate is higher. The CMP integrates respective advantages of the chemical polishing and the mechanical polishing, and can implement nano-level to atomic-level surface roughness. The CMP is used in the present disclosure, such that the polished surface of the semiconductor structure has higher precision.

Processing procedures of the insulating layers is shown in FIG. 8 and FIG. 11, including:

Step S301: depositing an insulating layer on the active area pillar, and etching the insulating layer to a preset height of the active area pillar to form a first insulating layer;

Step S302: over etching a part of the active area pillar beyond the preset height to reduce a cylinder of the active area pillar;

Step S303: forming a second insulating layer on the active area pillar after the active area pillar is cleaned; and

Step S304: depositing a titanium nitride layer on the second insulating layer, and etching back the titanium nitride layer to form the annular gate.

In Step S301, the insulating layers 5 and the first spacer 61 are formed in Step S20. After a photoresist is covered on the top of the word line structure, the CMP is performed on the first spacer by using a mask. The first spacer at the top of the word line structure is removed to expose the top of the insulating layer. Meanwhile, the insulating layer is etched by means of the mask, etching is stopped after the insulating layer is etched to a preset height to form a first insulating layer 51, and then the photoresist is removed.

The first insulating layer 51 is positioned at the bottom of the word line trench. The first spacer 61 formed by the first insulating layer 51 and silicon nitride fills up the bottom of the word line trench 1, and middle and upper portions of the word line trench 1 is left blank.

The insulating layer 5 may be etched by means of a dry etching process or a wet etching process or a combination thereof. Plasma etching, reactive ion etching, sputtering etching, ion polishing and so on may be used for dry etching. Selection of concrete types of dry etching and wet etching is not limited in the present disclosure, which may be selected according to actual usage requirements.

In Step S302, the first insulating layer 51 is formed in Step S301. The first insulating layer 51 has a preset height, and the first insulating layer 51 is arranged at a peripheral position on the bottom of the active area pillar 2. In this case, at the blank of the word line trench 1 left in Step S301, the peripheral position at the middle and upper portions of the active area pillar 2 are over etched. That is, a part of the active area pillar 2 beyond the preset height is over etched to reduce the cylinder of the active area pillar 2.

The peripheral position and the top of the active area pillar 2 are over etched, which may reduce the periphery of the active area pillar 2, that is, a radius of the cylinder of the active area pillar is reduced. In this way, a space between adjacent two active area pillars may be increased, such that sufficient space may be kept for subsequent formation of the annular gate.

In Step S303, after cleaning the active area pillar 2, a second insulating layer 52 is formed on the active area pillar 2. After the active area pillar 2 is over etched, because a contact via is provided or other conventional process operation is performed in advance in the word line structure, particles, organic matters, metal contaminants or other contaminants may exist on the surface of the base substrate. In this case, a cleaning process operation requires to be performed on the word line structure, to ensure cleanness of the word line structure and flatness of the base substrate. A next process operation may be performed on the cleaned word line structure.

After the word line structure is cleaned, oxide deposition is performed on the periphery and the top of the active area pillar whose diameter is reduced, such that a second insulating layer 52 is formed on the periphery and the top of the active area pillar. The second insulating layer 52 may be an oxide formed of silicon dioxide, silicon oxide or other insulating substances, which is not limited in the present disclosure. Materials of the second insulating layer 52 may be the same as or different from those of the first insulating layer 51, both of which may be silicon oxide, or may be oxide insulating layers formed of other different oxides, and types of the oxides need to meet actual needs of the present disclosure.

The bottom of the first insulating layer 51 and the bottom of the active area pillar 2 are positioned on the same straight line. The top of the first insulating layer 51 is connected to the bottom of the second insulating layer 52. The second insulating layer 52 is positioned at a peripheral position beyond coverage of the first insulating layer 51 and at the top of the active area pillar 2.

In Step S304, a titanium nitride layer is deposited on the second insulating layer, and the titanium nitride layer is etched back to form the annular gate. During the deposition of titanium nitride on the second insulating layer 52, titanium nitride is deposited at the blank of the word line trench and the top of the word line structure, such that titanium nitride is deposited to fill up the word line trench and the top of the active area pillar, to form a titanium nitride layer 7. Next, the titanium nitride layer 7 is etched, such that the titanium nitride layer 7 covering the active area pillar and the top of the word line trench is removed by means of etching. Next, rest of the titanium nitride layer 7 is continued to be etched back by means of a mask, such that the titanium nitride layer 7 is etched back to a certain height, thereby forming the annular gate.

The height of the annular gate is determined according to concrete usage of the annular gate in the semiconductor structure. The bottom of the annular gate is positioned at a connection between the first insulating layer and the second insulating layer, and the top of the annular gate is lower than the top of the active area pillar, such that a blank is left in a region of the word line trench between the second insulating layer and the first spacer. The annular gate is positioned on the second insulating layer. When the titanium nitride layer is etched back, shapes and structures of the first insulating layer, the second insulating layer and the first spacer are kept unchanged.

The titanium nitride layer may be deposited by means of atomic layer deposition, vacuum evaporation, magnetron sputtering, chemical vapor deposition, or physical vapor deposition, etc. furthermore, the titanium nitride layer is not only limited to a metal conductive layer formed by titanium nitride, and the titanium nitride layer also may be a metal conductive layer formed by metal having better conductivity such as tungsten, which is not enumerated here.

After the foregoing Steps S301 to S304 are performed, the annular gate perpendicular to the base substrate, i.e., the VGAA mentioned in the present disclosure, may be formed in the word line structure. In addition, the active area pillar is over etched in Step S303, which may increase margin for adjusting an integration process of the word line trench.

In Step S40, as shown in FIG. 12, the first spacer is etched back, such that the top of the first spacer is lower than the bottom of the annular gate. The annular gate positioned between the second insulating layer and the first spacer is formed in the foregoing steps. A photoresist layer is covered on the word line structure, and the first spacer is etched back by means of a mask, such that the height of the first spacer is etched back to a position lower than the bottom of the annular gate. That is, blanks are left between adjacent annular gates and a region of a word line trench above the annular gate, and the shapes and the structures of the first insulating layer, the second insulating layer and the annular gate are kept unchanged.

The first spacer may be etched back by means of a dry etching process or a wet etching process or a combination thereof. In the dry etching process, active groups for the substrate and the photoresist are produced in an atmosphere excited by plasma. In the wet etching process, the substrate is etched or the photoresist is stripped through immersion in a chemical reagent solution. Therefore, the dry etching may be employed to perform repeated etching and the wet etching is employed to remove the photoresist, or the dry etching or wet etching may be separately used, which may be flexibly selected according to actual process requirements of the present disclosure.

In Step S50, as shown in FIG. 13, a second spacer 62 is deposited at the top of the annular gate, and an air gap structure 8 is formed between the first spacer 61 and the second spacer 62. The second spacer is formed by means of low step coverage of silicon nitride or physical vapor deposition of silicon nitride. The second spacer is covered on the blank of the word line trench above the annular gate and on the top of the second insulating layer. The second spacer is configured to cover the top of the word line structure, and the air gap structure 8 is formed between the second spacer and the first spacer.

The air gap structure is positioned between adjacent two annular gates. The top of the air gap structure is higher than the top of the annular gate, and the bottom of the air gap structure needs to be lower than the bottom of the annular gate. That is, a hollow area of the air gap structure needs to be larger than an area between the adjacent two annular gates.

The second spacer may be formed by means of low step coverage of silicon nitride. A diffusion rate of silicon nitride on the base substrate is controlled to allow quick coverage and formation of silicon nitride at the blank of the word line trench, such that the hollow area is formed between the second spacer and the first spacer. That is, the air gap structure is formed between the second spacer and the first spacer.

The second spacer also may be formed by means of physical vapor deposition of silicon nitride. In the physical vapor deposition, the surface of silicon nitride vaporized into gaseous atoms or molecules or partially ionized into ions by means of a physical method in vacuum, and a spacer is deposited on the surface of the base substrate by means of a low-pressure gas or plasma process. The physical vapor deposition is a method for processing the surface of the word line structure. The physical vapor deposition used in the present disclosure may be vacuum evaporation, vacuum sputtering or vacuum ion plating, but the present disclosure is not limited thereto. In the present disclosure, quick coverage and formation of silicon nitride at the top of the word line structure is implemented by means of the physical vapor deposition, such that the air gap structure is formed between the second spacer and the first spacer.

Materials of the first spacer and the second spacer in the present disclosure may be silicon nitride or silicon oxynitride, or may be other insulating materials, which is not limited in the present disclosure.

In the method for forming a word line structure provided in the present disclosure, VGGA metal gates are formed on the base substrate, and a word line structure is formed between adjacent annular gates, such that a parasitic capacitance between the adjacent annular gates can be reduced, thereby reducing delay noise and improving device performance. In addition, the active area pillar is over etched, which increases the margin for integration of the semiconductors. Moreover, a double-layer insulating dielectric layer is formed for the second insulating layer and the second spacer in the word line structure, such that the insulation performance of the word line structure can be improved, thereby preventing the occurrence of a short circuit in the word line structure.

It is to be noted that steps of the method for forming a word line structure in the present disclosure are described in a particular order in the accompanying drawings. However, this does not require or imply to execute these steps necessarily according to the particular order, or this does not mean that the expected result cannot be implemented unless all the shown steps are executed. Additionally, some steps may be omitted, a plurality of steps may be combined into one step for execution, and/or one step may be decomposed into a plurality of steps for execution.

Another aspect of the present disclosure provides a word line structure, which includes a plurality of word line trenches and a plurality of active area pillars.

The plurality of active area pillars are divided by the plurality of word line trenches, where an insulating layer is arranged on each of the plurality of active area pillars, an annular gate is arranged on the insulating layer, a spacer is arranged between adjacent two of the annular gates, and an air gap structure is arranged in the spacer.

The bottom of the air gap structure is lower than that of the annular gate, and the top of the air gap structure is higher than that of the annular gate. That is, a hollow space area of the air gap structure is covered on the region between adjacent annular gates.

The insulating layer includes a first insulating layer and a second insulating layer, where the top of the first insulating layer is connected to the bottom of the second insulating layer, and the width between adjacent two of the second insulating layers is greater than the width between adjacent two of the first insulating layers. That is, after the active area pillar is over etched, the width of the second insulating layer formed on the surface of the over-etched active area pillar is greater than that of the first insulating layers, to reserve sufficient margin for the subsequent integration process.

The first insulating layer and the second insulating layer may be formed by means of chemical vapor deposition, physical vapor deposition, thermal evaporation, atomic layer deposition or the like. The first insulating layer and the second insulating layer are formed by an oxide insulating material, such that insulation protection may be provided to adjacent two word line structures by means of the two insulating layers, to prevent the occurrence of a short circuit between the word line structures and other surrounding structures, thereby reducing the short circuit risk of the device.

The spacer includes a first spacer and a second spacer, where the first spacer is positioned below the second spacer, and the first spacer and the second spacer are enclosed to form the air gap structure.

The second insulating layer and the second spacer positioned at the top of the active area pillar form a double-layer cap layer of the word line structure. As a double-layer insulating dielectric layer, the double-layer cap layer provides multiple insulation protection for the word line structure, thereby reducing the occurrence of the short circuit of the device.

The second spacer is formed by means of low step coverage of silicon nitride or physical vapor deposition. The method for forming the second spacer has been described above, and thus is not to be described again here.

In the word line structure provided in the present disclosure, an air gap structure is arranged in the word line structure, to reduce a parasitic capacitance between adjacent metal annular gates, thereby improving the device performance. In addition, the word line structure has the double-layer cap layer, such that the short circuit risk between adjacent word line structures can be reduced. Moreover, because the size of the active area pillar in the word line structure is reduced, the margin for the integration process is improved.

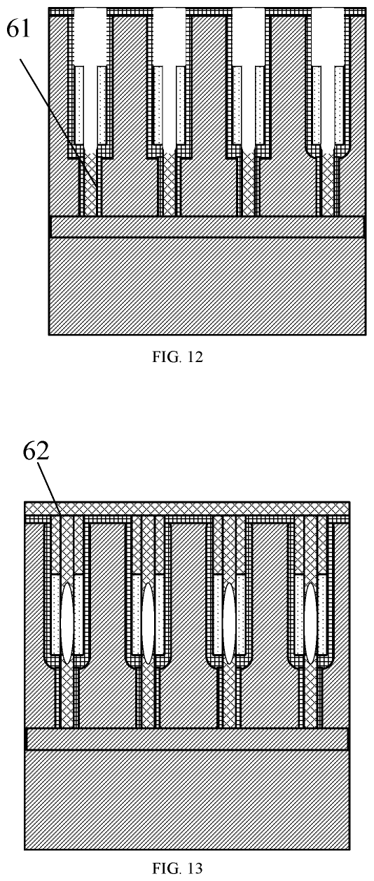

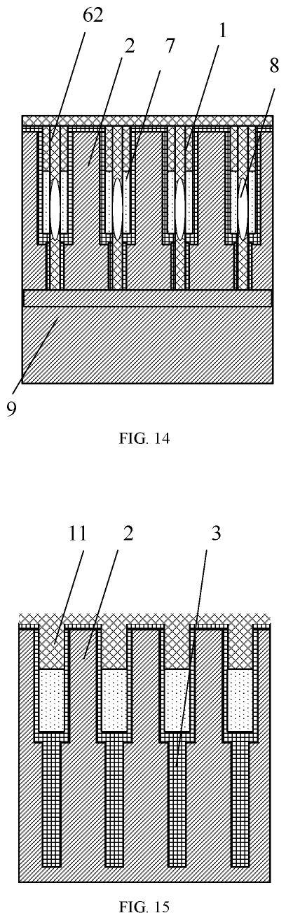

The present disclosure further provides a semiconductor structure. As shown in FIG. 14 and FIG. 15, the semiconductor structure includes a plurality of bit line structures and a plurality of word line structures.

The plurality of bit line structures and the plurality of word line structures are arranged vertically. The word line structure is a word line structure formed by means of the above method for forming a word line. An air gap structure 8 is arranged in every two adjacent annular gates in each of the plurality of word line structures. A size of the air gap structure is greater than or equal to that of the annular gate. That is, the size of a hollow space of the air gap structure is greater than or equal to that of a region between the adjacent annular gates.

In the present disclosure, a bit line in the bit line structure in the semiconductor structure is a buried bit line, and the bit line is lower than a word line in the word line structure.

In the process of forming the semiconductor structure of the present disclosure, the bit line structure first needs to be buried in the base substrate. The bit line is formed in the base substrate by means of diffusion deposition of cobalt silicide. Due to the diffusion of cobalt silicide, a cobalt silicide diffusion ring 9, that is, a circular region in FIG. 14, may be formed on the base substrate. After the bit line structure is formed, a word line structure is arranged perpendicular to the bit line structure. The method for forming a word line structure is described above, and thus detailed descriptions thereof are omitted here.

In some embodiments of the present disclosure, the air gap structure in the word line structure may be similarly formed in the bit line structure, such that the semiconductor structure may also have the bit line structure provided with the air gap structure. The semiconductor structure provided in the present disclosure may be vertically formed by the bit line structure and the word line structure provided with the air gap structure, or may be vertically formed by the word line structure and the bit line structure provided with the air gap structure, and structural adjustment may be flexibly made in the present disclosure according to actual performance requirements.

The semiconductor structure may be a DRAM or other memory devices, which are not enumerated one by one here. A VGAA structure is adopted for the semiconductor structure in the present disclosure, and a 2×2 arrangement form is adopted for a minimum integral unit on the base substrate. However, the present disclosure is not limited thereto.

In the semiconductor structure provided by the present disclosure, the word line structure provided with the air gap structure or the bit line structure provided with the air gap structure is arranged in the semiconductor structure, such that the parasitic capacitance of the semiconductor structure is reduced, and performance of the semiconductor structure is improved.

Other embodiments of the present disclosure will be apparent to those skilled in the art from consideration of the specification and practice of the invention disclosed here. This application is intended to cover any variations, uses, or adaptations of the present disclosure following the general principles thereof and including such departures from the present disclosure as come within known or customary practice in the art. It is intended that the specification and embodiments be considered as exemplary only, with a true scope and spirit of the present disclosure being indicated by the appended claims.

What is claimed is:

1. A method for forming a word line structure, comprising:
providing a base substrate comprising a substrate, and forming a plurality of word line trenches and a plurality of active area pillars arranged at intervals in the substrate;
forming insulating layers on the plurality of active area pillars, and filling a first spacer between adjacent two of the insulating layers;
processing each of the insulating layers, and forming an annular gate on the processed insulating layer;
etching back the first spacer, such that a top of the first spacer is lower than a bottom of the annular gate; and
depositing a second spacer at a top of the annular gate, and forming an air gap structure between the first spacer and the second spacer.

2. The method for forming a word line structure according to claim 1, wherein
the forming insulating layers on the plurality of active area pillars comprises:
depositing the insulating layer on a given one of the plurality of active area pillars, and etching the insulating layer to a preset height of the given active area pillar to form a first insulating layer.

3. The method for forming a word line structure according to claim 2, wherein
after the etching the first insulating layer to a preset height of the given active area pillar to form a first insulating layer, the method further comprises:
over etching a part of the given active area pillar beyond the preset height to reduce a cylinder of the given active area pillar; and
forming a second insulating layer on the given active area pillar after the given active area pillar is cleaned.

4. The method for forming a word line structure according to claim 3, wherein
after the forming a second insulating layer on the given active area pillar, the method comprises:
depositing a titanium nitride layer on the second insulating layer, and etching back the titanium nitride layer to form the annular gate.

5. The method for forming a word line structure according to claim 1, wherein
the depositing a second spacer at a top of the annular gate, and forming an air gap structure between the first spacer and the second spacer comprises:
depositing the second spacer by low step coverage, wherein the second spacer and the first spacer are enclosed to form the air gap structure.

6. The method for forming a word line structure according to claim 1, wherein
the depositing a second spacer at a top of the annular gate, and forming an air gap structure between the first spacer and the second spacer comprises:
depositing the second spacer by means of physical vapor deposition, wherein the second spacer and the first spacer are enclosed to form the air gap structure.

7. A word line structure, comprising:
a plurality of word line trenches; and
a plurality of active area pillars, the plurality of active area pillars being divided by the plurality of word line trenches, wherein an insulating layer is arranged on each of the plurality of active area pillars, an annular gate is arranged on the insulating layer, a spacer is arranged between adjacent two of the annular gates, and an air gap structure is arranged in the spacer.

8. The word line structure according to claim 7, wherein
a bottom of the air gap structure is lower than a bottom of the annular gate, and a top of the air gap structure is higher than a top of the annular gate.

9. The word line structure according to claim 7, wherein
the insulating layer comprises a first insulating layer and a second insulating layer, a top of the first insulating layer being connected to a bottom of the second insulating layer, and a width between adjacent two of the second insulating layers being greater than a width between adjacent two of the first insulating layers.

10. The word line structure according to claim 7, wherein
the spacer comprises a first spacer and a second spacer, the first spacer being positioned below the second spacer, and the first spacer and the second spacer being enclosed to form the air gap structure.

11. The word line structure according to claim 7, wherein
a second insulating layer and a second spacer positioned at a top of a given one of the plurality of active area pillars form a double-layer cap layer of the word line structure.

12. The word line structure according to claim 7, wherein
the second spacer is formed by means of low step coverage of silicon nitride.

13. The word line structure according to claim 7, wherein
the second spacer is formed by means of physical vapor deposition.

14. A semiconductor structure, comprising:
a plurality of bit line structures and the plurality of word line structures according to claim 7, wherein
the plurality of bit line structures and the plurality of word line structures are arranged vertically.

15. The semiconductor structure according to claim 14, wherein
an air gap structure is arranged in every two adjacent annular gates in each of the plurality of word line structures.

16. The semiconductor structure according to claim 15, wherein
a size of the air gap structure is greater than or equal to a size of the annular gate.

17. The semiconductor structure according to claim 14, wherein
a bit line in each of the plurality of bit line structures is a buried bit line, the bit line being lower than a word line in each of the plurality of word line structures.

18. The semiconductor structure according to claim 17, wherein
the bit line is formed by means of diffusion deposition of cobalt silicide.
